(19) United States
(12) Patent Application Publication
(10) Pub. No.: US 2016/0049324 A1
(43) Pub. Date: Feb. 18, 2016

(54) STACK, METHOD FOR TREATING SUBSTRATE MATERIAL, TEMPORARY FIXING COMPOSITION, AND SEMICONDUCTOR DEVICE

(71) Applicant: JSR Corporation, Minato-ku (JP)

(72) Inventors: Torahiko YAMAGUCHI, Minato-ku (JP); Kousuke Tamura, Minato-ku (JP); Tooru Matsumura, Minato-ku (JP); Keisuke Yajima, Minato-ku (JP); Araki Wakiuchi, Minato-ku (JP); Hiroyuki Ishii, Minato-ku (JP); Youichirou Maruyama, Minato-ku (JP); Katsumi Inomata, Minato-ku (JP)

(73) Assignee: JSR Corporation, Minato-ku (JP)

(21) Appl. No.: 14/805,880

(22) Filed: Jul. 22, 2015

(30) Foreign Application Priority Data
Aug. 13, 2014 (JP) 2014-164773
Jun. 11, 2015 (JP) 2015-118341

(51) Int. Cl. H01L 21/683; H01L 21/78; C08L 33/08; H01L 21/02

(52) U.S. Cl. CPC H01L 21/6836; H01L 21/02005; H01L 21/02057; H01L 21/78; C08L 33/08

(57) ABSTRACT

A stack includes a substrate material that has a circuit surface and that is temporarily fixed on a support via a temporary fixing material. The temporary fixing material includes a temporary fixing material layer (I) that is in contact with the circuit surface of the substrate material and a temporary fixing material layer (II) that is formed on the support-facing surface of the layer (I). The temporary fixing material layer (I) is formed of a temporary fixing composition (i) that includes a thermoplastic resin (Ai), a polyfunctional (meth)acrylate compound (Bi), and a radical polymerization initiator (Ci), and the temporary fixing material layer (II) is formed of a temporary fixing composition (ii) that includes a thermoplastic resin (Aii) and a release agent (Dii).

### BACKGROUND OF THE INVENTION

1. Field of the Invention

The present invention relates to a stack including a substrate material that has a circuit surface and that is temporarily fixed on a support via a temporary fixing material; a method for treating a substrate material; a feedstock composition for a temporary fixing material that can be suitably used to temporarily fix a substrate material on a support for treatment of the substrate material; and a semiconductor device.

2. Description of the Related Art

It has been proposed that a substrate material such as a semiconductor wafer is bonded to a support such as a glass substrate via a temporary fixing material before processes such as backgrinding of the substrate material and formation of back electrodes. It is necessary that the temporary fixing material be able to temporarily fix the substrate material on the support during processing and that the substrate material be readily separated from the support after the processing. Two-layered or three-layered temporary fixing materials have been proposed in consideration of properties such as adhesion, peeling, and heat resistance of the temporary fixing materials (see, for example, Patent Documents 1-3).

Patent Document 1 discloses a wafer processing laminate including a support, a temporary adhesive layer on the support, and a wafer laid contiguous to the temporary adhesive layer, the wafer having a circuit-forming front surface and a back surface to be processed. The temporary adhesive layer includes a first temporary bond layer (A) of a non-reactive thermoplastic organosiloxane polymer that is releasably bonded to the front surface of the wafer and a second temporary bond layer (B) of a thermosetting modified siloxane polymer that is laid contiguous to the first temporary bond layer and that is releasably bonded to the support.

### RELATED ART DOCUMENTS

### Patent Documents

Patent Document 1: JP 2013-048215 A

Patent Document 2: JP 2013-110391 A

Patent Document 3: JP 2013-179135 A

### SUMMARY OF THE INVENTION

### Problems to be Solved by the Invention

Through their research, the inventors of the present invention have found that conventional multilayered temporary fixing materials cause the problem of damaging a bump formed on a circuit surface of a substrate material when the substrate material is separated from a support. The problem tends to occur especially when the bump is a pillar bump that includes a copper portion and a solder portion.

An object of the present invention is to provide a method for treating a substrate material, the method capable of successfully preventing damage to the substrate material when the substrate material is separated from a support, i.e., achieving high yield; a stack including a substrate material that is retained to a support via a temporary fixing material; a feedstock composition for a temporary fixing material suitably used in the treatment method; and a semiconductor device.

### Means of Solving the Problems

As a result of assiduous research intended to solve the problem described above, the inventors of the present invention have found that the problem can be solved by a stack and a method for treating a substrate material as described below, thereby completing the present invention.

The present invention relates to, for example, the following aspects [1]-[10].

[1] A stack including a substrate material that has a circuit surface and that is temporarily fixed on a support via a temporary fixing material, wherein the temporary fixing material includes a temporary fixing material layer (I) that is in contact with the circuit surface of the substrate material and a temporary fixing material layer (II) that is formed on the support-facing surface of the layer (I), wherein the temporary fixing material layer (I) is formed of a temporary fixing composition (i) that includes a thermoplastic resin (Ai), a polyfunctional (meth)acrylate compound (Bi), and a radical polymerization initiator (Ci), and wherein the temporary fixing material layer (II) is formed of a temporary fixing composition (ii) that includes a thermoplastic resin (Aii) and a release agent (Dii).

[2] The stack according to [1], wherein the temporary fixing composition (ii) does not substantially include a radical polymerization initiator (Cii).

[3] The stack according to [1] or [2], wherein the temporary fixing composition (ii) further includes a radical polymerization inhibitor (EU).

[4] The stack according to any one of [1]-[3], wherein the temporary fixing composition (i) includes a difunctional (meth)acrylate as the polyfunctional (meth)acrylate compound (Bi).

[5] The stack according to any one of [1]-[4], wherein the temporary fixing composition (i) has a content of the polyfunctional (meth)acrylate compound (Bi) of 0.5-50 parts by mass based on 100 parts by mass of the thermoplastic resin (Ai).

[6] The stack according to any one of [1]-[5], wherein the temporary fixing composition (i) further includes a diene polymer (Fi).

[7] A method for treating a substrate material, the method including <1> a step of forming the stack according to any one of [1]-[6], <2> a step of processing the substrate material and/or transporting the stack, and <3> a step of separating the substrate material from the support.

[8] The treatment method according to [7], the method further including <4> a step of cleaning the substrate material.

[9] A temporary fixing composition including a thermoplastic resin (Ai), a polyfunctional (meth)acrylate compound (Bi), and a radical polymerization initiator (Ci).

[10] A semiconductor device obtained by the treatment method according to [7] or [8].

### Effects of the Invention

The present invention can provide a method for treating a substrate material, the method capable of successfully preventing damage to the substrate material when the substrate material is separated from a support, i.e., achieving high yield; a stack including a substrate material that is retained to a support via a temporary fixing material; a feedstock composition for a temporary fixing material suitably used in the treatment method; and a semiconductor device.

### BRIEF DESCRIPTION OF THE DRAWINGS

FIG. 1 is a cross-sectional view of a stack according to an embodiment of the present invention.

FIG. 2 illustrates separation of a substrate material from a support.

### DESCRIPTION OF THE EMBODIMENTS

Now, a stack according to the present invention and a temporary fixing composition, which is a feedstock composition for a temporary fixing material that constitutes the stack, will be described, and then a method for treating a substrate material and a semiconductor device obtained by the treatment method will be described.

As used herein, the term temporary fixing material refers to a material that is used to temporarily fix a substrate material on a support so that the substrate material may not move and slide relative to the support during processing and/or transportation of the substrate material. Examples of the processing include dicing; backgrinding; and photofabrication processing such as resist patterning, formation of metal bumps by plating or the like, film formation by chemical vapor deposition or the like, and reactive ion etching (RIE). Examples of the transportation include transportation of substrate materials between apparatuses.

1. Stack

The stack of the present invention includes a substrate material that has a circuit surface and that is temporarily fixed on a support via a temporary fixing material. The temporary fixing material includes a temporary fixing material layer (I) that is in contact with the circuit surface of the substrate material and a temporary fixing material layer (II) that is formed on the support-facing surface of the layer (I).

The temporary fixing material layer (I) is formed of a temporary fixing composition (i) that includes a thermoplastic resin (Ai), a polyfunctional (meth)acrylate compound (Bi), and a radical polymerization initiator (Ci) as described below. Preferably, the layer (I) is formed by curing the composition (i), and the circuit surface of the substrate material is protected by the layer (I). Thus, in a step of separating the substrate material from the support, for example, bumps formed on the circuit surface can be prevented from being damaged. The temporary fixing material layer (I) is hereinafter also simply referred to as “layer (I)”.

The temporary fixing material layer (II) is formed of a temporary fixing composition (ii) that includes a thermoplastic resin (Aii) and a release agent (Dii), as described below. In a step of separating the substrate material from the support, mainly, separation at the interface between the support and the temporary fixing material layer (II) or separation in the temporary fixing material layer (II) due to cohesive failure occurs. The temporary fixing material layer (II) is hereinafter also referred to as “release layer (II)”.

In the present invention, the temporary fixing material includes the layer (I) and the release layer (II) that is formed on the layer (I). Such two or more layered temporary fixing material can provide properties such as protection of the circuit surface of the substrate material, adhesion between the substrate material and the support, peeling property of the substrate material from the support, and heat resistance during processing, in a balanced manner.

In the present invention, it is preferred to use a composition that further includes a diene polymer (Fi) as the temporary fixing composition (i) to form the layer (I). In this case, the temporary fixing material exhibits improved cleanability, which is the ability to remove, by using a solvent in the cleaning step, a residue of the layer (I) remaining on the substrate material in the separating step.

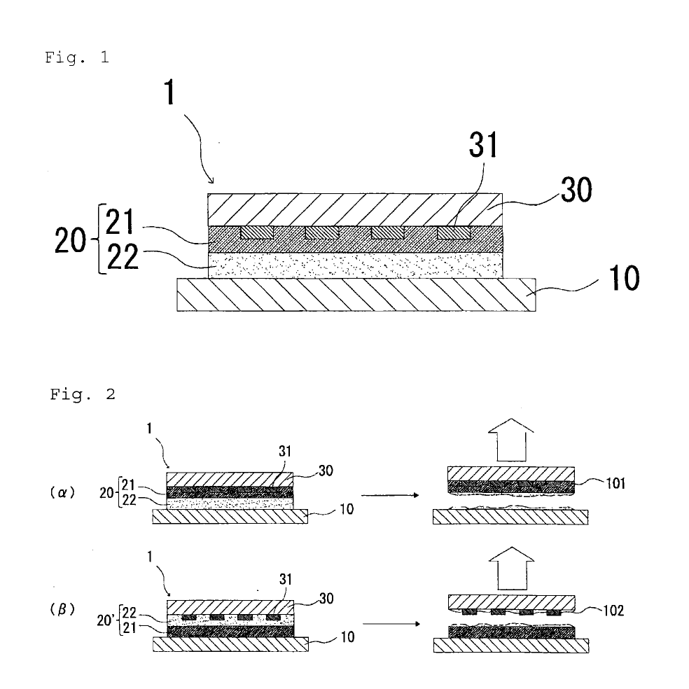

FIG. 1 illustrates an example of a stack according to the present invention. The stack 1 includes a support 10, a temporary fixing material 20 that is formed on the support 10, and a substrate material 30 that is temporarily fixed on the support 10 using the temporary fixing material 20 and that has bumps 31. The temporary fixing material 20 includes a layer (I) 21 that is in contact with a circuit surface of the substrate material 30 and a release layer (II) 22 that is formed on the layer (I) 21 and that is in contact with the support 10.

FIG. 2(α) illustrates an exemplary separation of the substrate material 30 from the support 10 in the stack according to the present invention. FIG. 2(β) illustrates an exemplary separation in the case of using a temporary fixing material 20′ including a release layer (II) 22 that is in contact with a circuit surface of the substrate material 30 and a layer (I) 21 that is formed on the release layer (II) 22 and that is in contact with the support 10.

In the example illustrated in FIG. 2(β), separation occurs in the release layer (II) 22 that is in contact with a circuit surface of the substrate material 30, and thus bumps 31 may be damaged during the separating step. In contrast, in the example of the present invention illustrated in FIG. 2(α), the layer (I) 21 protects the circuit surface of the substrate material 30, and separation usually occurs in the release layer (II) 22 that is in contact with the support 10. This can prevents bumps 31 from being damaged during the separating step.

In the stack of the present invention, the temporary fixing material may include any other layer, in addition to the layer (I) and the release layer (II). For example, an interlayer may be disposed between the layer (I) and the release layer (II), or another layer may be disposed between the release layer (II) and the support. Particularly preferred is a two-layered temporary fixing material that consists of the layer (I) and the release layer (II).

The total thickness of the temporary fixing material may be selected as desired depending on the size of a temporary fixation surface of a substrate material and the extent of adhesion to be needed during processing or the like. The temporary fixing material usually has a total thickness of from 0.1 μm to 1 mm inclusive, preferably from 1 μm to 0.5 mm inclusive, and more preferably from 10 μm to 0.3 mm inclusive. The layer (I) and the release layer (II) each usually have a thickness of 0.1-500 μm, preferably 1-250 μm, and more preferably 10-150 μm. When these thicknesses are within the respective ranges described above, the temporary fixing material has sufficient retention to temporarily fix the substrate material, and the substrate material does not separate from the temporary fixation surface during processing or transportation.

The temporary fixing materials as described above are suitably used to temporarily fix a substrate material in various processes in current economic activities, such as, for example, micromachining of various material surfaces, various surface mounting processes, and transportation of semiconductor wafers and semiconductor elements.

2. Temporary Fixing Composition

2-1. Temporary Fixing Composition (i)

The temporary fixing composition (i) includes a thermoplastic resin (Ai), a polyfunctional (meth)acrylate compound (Bi), and a radical polymerization initiator (Ci). Preferably, the composition (i) further includes a diene polymer (Fi).

<Thermoplastic Resin (Ai)>

Examples of the thermoplastic resin (Ai) include cycloolefin polymers, petroleum resins, and novolak resins. The (Ai) may be used alone or in combination of two or more. Among them, the cycloolefin polymers are preferred.

A layer that includes a cycloolefin polymer has excellent heat resistance and has high resistance to chemicals used in photofabrication, such as, for example, highly polar organic solvents or aqueous chemicals. Thus, when a process for processing a substrate material involves an operation at high temperature, the layer can prevent damage to the substrate material itself and parts such as bumps formed on a circuit surface of the substrate material.

The layer formed of the composition (i) that includes a cycloolefin polymer, a polyfunctional (meth)acrylate compound (Bi), and a diene polymer (Fi) can be easily removed by treating the layer with a solvent such as, for example, a less polar organic solvent in the cleaning step, even when the layer is cured.

In the temporary fixing composition (i) of the present invention, the content of the thermoplastic resin (Ai) is usually from 30 to 95% by mass, preferably from 40 to 90% by mass, and more preferably from 50 to 90% by mass based on the total solids content taken as 100% by mass. As used herein, “solids content” refers to all non-solvent ingredients. The content of the (Ai) within the range described above is preferred in that temperature is lowered when the substrate material is temporarily fixed on the support and in that the substrate material may not move and slide relative to the support during processing and/or transportation of the substrate material.

<<Cycloolefin Polymer>>

Examples of the cycloolefin polymer include addition copolymers of a cyclic olefin compound and a non-cyclic olefin compound, ring-opening metathesis polymers of one or more kinds of cyclic olefin compounds, and hydrogenated polymers of the ring-opening metathesis polymers. The cycloolefin polymers can be synthesized by a conventionally known method.

Examples of the cyclic olefin compound include norbornene olefins, tetracyclododecene olefins, dicyclopentadiene olefins, and derivatives thereof. Examples of the derivatives include substituted derivatives that have one or more selected from alkyl groups, alkylidene groups, aralkyl groups, cycloalkyl groups, a hydroxy group, alkoxy groups, an acetyl group, a cyano group, amide groups, imide groups, silyl groups, aromatic rings, an ether bond, and an ester bond.

The number of carbon atoms in the substituents in these derivatives are preferably as follows: The alkyl groups preferably have 1 to 20 and more preferably 1 to 10 carbon atoms. The alkylidene group preferably has 1 to 20 and more preferably 1 to 10 carbon atoms. The aralkyl group preferably has 7 to 30 and more preferably 7 to 18 carbon atoms. The cycloalkyl group preferably has 3 to 30 and more preferably 3 to 18 carbon atoms. The alkoxyl group preferably has 1 to 10 carbon atoms.

Suitable examples of the cyclic olefin compound include a compound represented by Formula (Al):

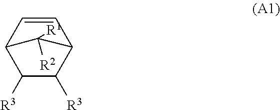

In Formula (A1), R¹ to R³ are as follows. R¹ and R² are each independently a hydrogen atom or an alkyl group. R³ are each independently a hydrogen atom, an alkyl group, a cycloalkyl group, an aryl group, an aralkyl group, an alkoxyl group, an alkoxycarbonyl group, an aldehyde group, an acetyl group, or a nitrile group. The two R³ may be linked together to form a ring structure such as an alicyclic structure, and, for example, the alicyclic structure may have a substituent selected from the groups listed above for R³.

The numbers of carbon atoms in the groups in Formula (A1) are preferably as follows: The alkyl group preferably has 1 to 20 and more preferably 1 to 10 carbon atoms. The cycloalkyl group preferably has 3 to 30 and more preferably 3 to 18 carbon atoms. The aryl group preferably has 6 to 18 carbon atoms. The aralkyl group preferably has 7 to 30 and more preferably 7 to 18 carbon atoms. The alkoxyl group preferably has 1 to 10 carbon atoms. The alkoxycarbonyl group preferably has 2 to 11 carbon atoms.

Examples of the non-cyclic olefin compound include linear or branched olefins having 2 to 20 and preferably 2 to 10 carbon atoms. Ethylene, propylene, and butene are more preferred, and ethylene is particularly preferred.

<Addition Copolymers>

For example, the addition copolymers of a cyclic olefin compound and a non-cyclic olefin compound include a structural unit represented by Formula (AI) and a structural unit derived from a non-cyclic olefin compound (a structural unit resulting from the reaction of a polymerizable double bond of the non-cyclic olefin).

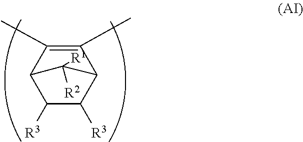

R¹ to R³ in Formula (AI) are the same as defined in Formula (A1).

Examples of commercially available addition copolymers include TOPAS manufactured by TOPAS ADVANCED POLYMERS and APEL manufactured by Mitsui Chemicals, Inc.

<Ring-Opening Metathesis Polymers and Hydrogenated Products Thereof>

Examples of the ring-opening metathesis polymers of one or more kinds of cyclic olefin compounds include polymers having a structural unit represented by Formula (AII). Examples of the hydrogenated polymers of the ring-opening metathesis polymers include polymers having a structural unit represented by Formula (AIII).

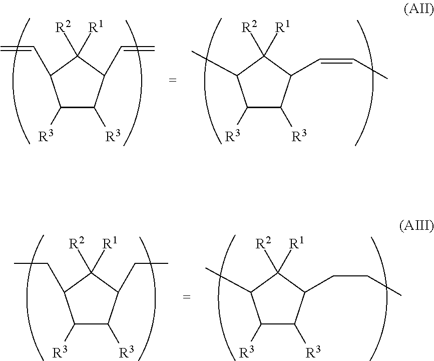

R¹ to R³ in Formulae (AII) and (AIII) are the same as defined in Formula (A1).

Examples of commercially available ring-opening metathesis polymers include ZEONOR and ZEONEX manufactured by ZEON Corp. and ARTON manufactured by JSR Corp.

The cycloolefin polymer usually has a weight average molecular weight (Mw) of 10,000-100,000 and preferably 30,000-100,000 as measured by gel permeation chromatography (GPC) relative to polystyrene standards. The cycloolefin polymer usually has a molecular weight distribution Mw/Mn of 2-4 and preferably 3-4, wherein Mn is the number average molecular weight of the polymer, as measured by gel permeation chromatography (GPC) relative to polystyrene standards.

<<Petroleum Resins>>

Examples of the petroleum resins include C5 petroleum resins, C9 petroleum resins, C5/C9 mixed petroleum resins, cyclopentadiene resins, vinyl-substituted aromatic compound polymers, olefin/vinyl-substituted aromatic compound copolymers, cyclopentadiene compound/vinyl-substituted aromatic compound copolymers, hydrogenated products thereof, and mixtures thereof. Among them, the C5 petroleum resins, the C9 petroleum resins, the C5/C9 mixed petroleum resins, the cyclopentadiene resins, the vinyl-substituted aromatic compound polymers, hydrogenated products thereof, and mixtures thereof are preferred. Preferred example of the C5 petroleum resins include aliphatic resins. Preferred examples of the C9 petroleum resins include alicyclic resins. Among them, the C9 petroleum resins, the cyclopentadiene resins, hydrogenated products thereof, and mixtures thereof are particularly preferred.

The petroleum resin usually has a weight average molecular weight (Mw) of not more than 20,000, preferably 100-20,000, more preferably 200-10,000, and particularly preferably 300-5,000 as measured by GPC relative to polystyrene standards.

<<Novolak Resins>>

The novolak resins can be obtained, for example, by condensation of phenols and aldehydes in the presence of an acid catalyst such as oxalic acid.

Examples of the phenols include phenol, o-cresol, m-cresol, p-cresol, o-ethylphenol, m-ethylphenol, p-ethylphenol, o-butylphenol, m-butylphenol, p-butylphenol, 2,3-xylenol, 2,4-xylenol, 2,5-xylenol, 2,6-xylenol, 3,4-xylenol, 3,5-xylenol, 2,3,5-trimethylphenol, 3,4,5-trimethylphenol, catechol, resorcinol, pyrogallol, α-naphthol, and β-naphthol.

Examples of the aldehydes include formaldehyde, paraformaldehyde, acetaldehyde, and benzaldehyde. Specific preferred examples of the novolak resins include phenol/formaldehyde novolak resin, cresol/formaldehyde novolak resin, and phenol-naphthol/formaldehyde novolak resin.

The novolak resin usually has a weight average molecular weight of 2,000 or more and preferably 2,000-20,000 as measured by GPC relative to polystyrene standards. The molecular weight distribution Mw/Mn of the novolak resin is usually 1 to 10 and preferably 1.5 to 5, wherein Mn is the number average molecular weight of the resin as measured by GPC relative to polystyrene standards.

<Polyfunctional (Meth)Acrylate Compound (Bi)>

The polyfunctional (meth)acrylate compound (Bi) is a compound that has two or more (meth)acryloyloxy groups. The number of (meth)acryloyloxy groups in the (Bi) is preferably from 2 to 6, more preferably from 2 to 3, and particularly preferably 2. The compound (Bi) is a component that is polymerized to form a cured layer when the composition (i) is used to form the layer (I).

Examples of the compound (Bi) include

difunctional (meth)acrylates such as aliphatic or cycloaliphatic diol di(meth)acrylates such as ethylene glycol di(meth)acrylate, propylene glycol di(meth)acrylate, 1,4-butanediol di(meth)acrylate, 1,6-hexanediol di(meth)acrylate, 1,9-nonanediol di(meth)acrylate, 1,10-decanediol di(meth)acrylate, neopentyl glycol di(meth)acrylate, and tricyclodecane dimethanol di(meth)acrylate,

polyalkylene glycol di(meth)acrylates such as diethylene glycol di(meth)acrylate, triethylene glycol di(meth)acrylate, tetraethylene glycol di(meth)acrylate, polyethylene glycol di(meth)acrylate, dipropylene glycol di(meth)acrylate, tripropylene glycol di(meth)acrylate, polypropylene glycol di(meth)acrylate, polytetramethylene glycol di(meth)acrylate, and polyethylene/polypropylene glycol di(meth)acrylate,

aliphatic triol di(meth)acrylates such as glycerin di(meth)acrylate and trimethylolpropane di(meth)acrylate,

bisphenol di(meth)acrylates such as ethoxylated bisphenol A di(meth)acrylate, propoxylated bisphenol A di(meth)acrylate, propoxylated ethoxylated bisphenol A di (meth) acrylate, and epoxy (meth)acrylate that is obtained by adding a (meth)acrylic acid to bisphenol A diglycidyl ether, and other di(meth)acrylates such as 2,2-bis[4-((meth)acryloxyethoxy)phenyl]propane, 9,9-bis[4-(2-acryloyloxyethoxy)phenyl]fluorene, 2-hydroxy-3-(meth)acryloyloxypropyl (meth) acrylate, tris(2-hydroxyethyl)isocyanurate di(meth)acrylate; and trifunctional or higher (meth)acrylates such as pentaerythritol tri(meth)acrylate, pentaerythritol tetra(meth)acrylate, trimethylolpropane tri(meth)acrylate, PO(propylene oxide) modified trimethylolpropane tri(meth)acrylate, tetramethylolpropane tetra(meth)acrylate, ditrimethylolpropane tetra(meth)acrylate, dipentaerythritol poly(meth)acrylate, dipentaerythritol penta(meth)acrylate, dipentaerythritol hexa(meth)acrylate, ethoxylated glycerin tri(meth)acrylate, ethoxylated pentaerythritol tetra(meth)acrylate, tris(2-hydroxyethyl) isocyanurate tri(meth)acrylate, ethoxylated isocyanuric acid tri(meth)acrylate, ε-caprolactone modified tris-(2-(meth)acryloxyethyl) isocyanurate, and polyester (meth) acrylates (trifunctional or higher).

Among them, the difunctional (meth) acrylates are preferred for ease of cleaning the cured layer.

Usually, the molecular weight of the compound (Bi) is, but not limited to, from 200 to 10,000.

The compound (Bi) may be used alone or in combination of two or more.

In the composition (i) of the present invention, the content of the polyfunctional (meth) acrylate compound (Bi) is usually from 0.5 to 50 parts by mass, preferably 1-30 parts by mass, and more preferably 2-15 parts by mass based on 100 parts by mass of the thermoplastic resin (Ai). The content of the (Bi) within the range described above is preferred for ease of cleaning the cured layer.

<Radical Polymerization Initiator (Ci)>

The radical polymerization initiator (Ci) acts as an initiator for the polymerization of the polyfunctional (meth)acrylate compound (Bi) and the diene polymer (Fi) as described below.

Examples of the initiator (Ci) that can be used include known compounds such as, for example, thermal polymerization initiators and photopolymerization initiators.

Examples of the thermal polymerization initiators include organic peroxides such as hydroperoxides such as diisopropylbenzene hydroperoxide, cumene hydroperoxide, and t-butyl hydroperoxide, dialkyl peroxides such as t-butyl cumyl peroxide, di-t-butyl peroxide, and di-t-hexyl peroxide, peroxyesters such as cumyl peroxyneodecanoate, 1,1,3,3-tetramethylbutyl peroxyneodecanoate, and t-hexyl peroxyneodecanoate, diacyl peroxides such as diisobutyryl peroxide, di(3,5,5-trimethylhexanoyl) peroxide, and dilauroyl peroxide, peroxydicarbonates such as diisopropyl peroxydicarbonate, di-n-propyl peroxydicarbonate, and bis(4-t-butyl cyclohexyl)peroxydicarbonate, and peroxyketals such as 2,2-bis(4,4-di-t-butylperoxycyclohexyl)propane, 1,1-di(t-hexylperoxy)cyclohexane, and 1,1-di(t-butylperoxy)cyclohexane; and azo compounds such as 2,2′-azobisisobutyronitrile, 2,2′-azobis(4-methoxy-2,4-dimethylvaleronitrile), 2,2′-azobis(2-cyclopropylpropionitrile), 2,2′-azobis(2,4-dimethylvaleronitrile), 2,2′-azobis(2-methylbutyronitrile), 1,1′-azobis(cyclohexane-1-carbonitrile), 2-(carbamoylazo)isobutyronitrile, 2-phenylazo-4-methoxy-2,4-dimethylvaleronitrile, 2,2′-azobis(2-amidinopropane)dihydrochloride, 2,2′-azobis(N,N′-dimethyleneisobutylamidine), 2,2′-azobis[2-methyl-N-(2-hydroxyethyl)-propionamide], 2,2′-azobis(isobutylamide)dihydrate, 4,4′-azobis(4-cyanopentanoic acid), 2,2′-azobis(2-cyanopropanol), dimethyl-2,2′-azobis(2-methyl propionate), and 2,2′-azobis[2-methyl-N-(2-hydroxyethyl)propionamide].

Examples of the photopolymerization initiators include biimidazole compounds such as 2,2′-bis(2,4-dichlorophenyl)-4,5,4′,5′-tetraphenyl-1,2′-biimidazole, 2,2′-bis(2-chlorophenyl)-4,5,4′,5′-tetraphenyl-1,2′-biimidazole, 2,2′-bis(2,4-dichlorophenyl)-4,5,4′,5′-tetraphenyl-1,2′-biimidazole, 2,2′-bis(2,4-dimethylphenyl)-4,5,4′,5′-tetraphenyl-1,2′-biimidazole, 2,2′-bis(2-methylphenyl)-4,5,4′,5′-tetraphenyl-1,2′-biimidazole, and 2,2′-diphenyl-4,5,4′,5′-tetraphenyl-1,2′-biimidazole;

alkylphenone compounds such as diethoxyacetophenone and 2-(4-methylbenzyl)-2-dimethylamino-1-(4-morpholinophenyl)buta none;

acylphosphine oxide compounds such as 2,4,6-trimethylbenzoyl diphenylphosphine oxide; triazine compounds such as 2,4-bis(trichloromethyl)-6-(4-methoxyphenyl)-1,3,5-triazine and 2,4-bis(trichloromethyl)-6-(4-methoxynaphthyl)-1,3,5-triazine; benzoin compounds such as benzoin; and benzophenone compounds such as benzophenone, methyl o-benzoyl benzoate, and 4-phenylbenzophenone.

Among them, the organic peroxides are preferred for storage stability of the temporary fixing composition (i).

The initiator (Ci) may be used alone or in combination of two or more. In the composition (i) of the present invention, the content of the radical polymerization initiator (Ci) is usually from 1 to 50 parts by mass, preferably from 5 to 40 parts by mass, and more preferably from 10 to 30 parts by mass based on 100 parts by mass of the polyfunctional (meth)acrylate compound (Bi). The content of the (Ci) within the range described above is preferred for storage stability of the temporary fixing composition (i).

<Diene Polymer (Fi)>

Preferably, the composition (i) of the present invention includes a diene polymer (Fi). The layer (I) formed of the composition (i) may remain as a residue on the substrate material, after the substrate material is separated from the support. The layer (I) formed of the composition (i) that includes the diene polymer (Fi) can be removed using a solvent. In particular, use of a cycloolefin polymer as the thermoplastic resin (Ai) and use of the diene polymer (Fi) can enhance the removability.

Examples of the diene polymer (Fi) include conjugated diene polymers. Examples of conjugated diene compounds that constitute the conjugated diene polymers include 1,3-butadiene, 2-methyl-1,3-butadiene(isoprene), 2,3-dimethyl-1,3-butadiene, 1,3-pentadiene, 2-methyl-1,3-pentadiene, 1,3-hexadiene, 1,3-octadiene, 3-butyl-1,3-octadiene, and 4,5-diethyl-1,3-octadiene. Among them, 1,3-butadiene and isoprene are preferred. The conjugated diene polymers may have a structural unit derived from a compound other than the conjugated diene compounds. Examples of the compound include monomers such as isobutylene, acrylonitrile and aromatic compounds that include a polymerizable double bond such as styrene.

In particular, the examples include polybutadiens, polyisoprenes, butadiene-isoprene copolymers, isobutylene-isoprene copolymers, acrylonitrile-butadiene copolymers, styrene-butadiene copolymers, styrene-isoprene copolymers, and styrene-isoprene-butadiene copolymers.

The diene polymer (Fi) preferably has a vinyl bond content of 10-100% and more preferably 20-80%. Use of the diene polymer (Fi) having a vinyl bond content within the range allows formation of the layer (I) that includes a reaction product with the polyfunctional (meth)acrylate compound (Bi).

The vinyl bond content refers to a total percentage (on a mole basis) of 1,2-bond units and 3,4-bond units in conjugated diene compound units incorporated in 1,2-, 3,4-, and 1,4-fashions into the diene polymer (Fi). The vinyl bond content can be determined by infrared spectroscopy (Morello method).

The number average molecular weight (Mn) of the diene polymer (Fi) is usually from 1,000 to 100,000 and preferably from 1,500 to 10,000, as measured by GPC relative to polystyrene standards.

In the diene polymer (Fi), the content of a structural unit derived from the conjugated diene is preferably equal to or more than 5% by mass and more preferably equal to or more than 10% by mass in terms of the reactivity with the polyfunctional (meth)acrylate compound (Bi).

Example of commercially available diene polymers (Fi) include “Ricon 100” (styrene-butadiene rubber with a number average molecular weight of 4500, a styrene content of 25% by mass, and a vinyl bond content of the butadiene portion of 70%), “Ricon 181” (styrene-butadiene rubber with a number average molecular weight of 3200, a styrene concent of 28% by mass, and a vinyl bond content of the butadiene portion of 30%), “Ricon 130” (butadiene rubber with a number average molecular weight of 2500 and a vinyl bond content of 28%), “Ricon 131” (butadiene rubber with a number average molecular weight of 4500 and a vinyl bond content of 28%), “Ricon 134” (butadiene rubber with a number average molecular weight of 8000 and a vinyl bond content of 28%), “Ricon 142” (butadiene rubber with a number average molecular weight of 3900 and a vinyl bond content of 55%), “Ricon 150” (butadiene rubber with a number average molecular weight of 3900 and a vinyl bond content of 70%), and “Ricon 154” (butadiene rubber with a number average molecular weight of 5200 and a vinyl bond content of 90%) manufactured by SARTOMER; and “LBR-352” (butadiene rubber with a number average molecular weight of 9000) and “L-SBR-820” (styrene-butadiene rubber with a number average molecular weight of 8500) manufactured by Kuraray Co., Ltd.

In the temporary fixing composition (i) of the present invention, the content of the diene polymer (Fi) is usually from 1 to 80 parts by mass, preferably from 5 to 50 parts by mass, and more preferably from 10 to 40 parts by mass based on 100 parts by mass of the thermoplastic resin (Ai). The content of the diene polymer (Fi) within the range described above is preferred for removability with a solvent, adhesion, peeling property, and heat resistance of the temporary fixing material.

In the present invention, it is particularly preferred to use the composition (i) that includes a cycloolefin polymer as the thermoplastic resin (Ai) and that includes the polyfunctional (meth)acrylate compound (Bi) and the diene polymer (Fi). The layer obtained from the composition can be readily removed using a solvent. Thus, the layer (I) (residue) remaining on the substrate material after the separating step can be readily removed using a solvent for a cleaning step.

2-2. Temporary Fixing Composition (Ii)

The temporary fixing composition (ii) includes a thermoplastic resin (Aii) and a release agent (Dii).

<Thermoplastic resin (Aii)>

Examples of the thermoplastic resin (Aii) can include compounds similar to those listed above for the thermoplastic resin (Ai), and preferred compounds are also similar to those listed above for the thermoplastic resin (Ai). The resin (Ai) in the composition (i) and the resin (Aii) in the composition (ii) may be the same or different compound.

In the composition (ii), the content of the thermoplastic resin (Aii) is usually from 30 to 95% by mass, preferably from 40 to 90% by mass, and more preferably from 50 to 85% by mass based on the total solids content taken as 100% by mass. As used herein, “solids content” refers to all non-solvent ingredients. The content of the (Aii) within the range described above is preferred in that temperature is lowered when the substrate material is temporarily fixed on the support and in that the substrate material may not move and slide relative to the support during processing and/or transportation of the substrate material.

<Radical Polymerization Initiator (Cii)>

Preferably, the composition (ii) does not substantially include a radical polymerization initiator (Cii). Examples of the initiator (Cii) can include compounds similar to those listed above for the compounds (Ci).

The term “do not substantially include” means that in the composition (ii), the content of the radical polymerization initiator (Cii) is equal to or less than 0.01% by mass, more preferably equal to or less than 0.001% by mass, and still more preferably 0% by mass based on the total solids content taken as 100% by mass.

When the composition (ii) does not substantially include the radical polymerization initiator (Cii), the release layer (II) formed of the composition (ii) will not be cured as much as the layer (I), even when, for example, the layer (II) is exposed to high temperature during processing. Thus, the release layer (II) allows easy separation of the substrate material from the support.

<Release Agent (Dii)>

The composition (ii) includes a release agent (Dii). The release agent (Dii) migrates to the surface of the layer during the temporary fixing composition (ii) that includes the release agent (Dii) being applied and dried, and thus the release agent (Dii) is present at a higher concentration on the surface of the layer than in the interior of the layer. This may be contribute to the peeling property of the layer.

Preferably, the release agent (Dii) has a functional group that can react with the diene polymer (Fii) to form a chemical bond. Such compound reacts with the (Fii) upon heating and/or light irradiation to be incorporated into the release layer (II), and the ingredients of the release agent in the release layer (II) are less likely to migrate to the other layers such as the layer (I).

Therefore, when the substrate material is separated from the support, separation at the interface between the layer (I) and the substrate material and separation in the layer (I) due to cohesive failure are less likely to occur, while mainly, separation at the interface between the support and the release layer (II) or separation in the release layer (II) due to cohesive failure is likely to occur. Thus, bumps and the like on the substrate material are less likely to be damaged in the separating step.

Examples of the functional group, in the release agent (Dii), that can react with the (Fii) to form a chemical bond include groups having a polymerizable double bond (hereinafter also referred to as “groups including a polymerizable double bond”). Examples of the groups include alkenyl groups such as a vinyl group and an allyl group, and (meth)acryloyl groups. The (meth)acryloyl groups are more preferred.

Preferably, the release agent (Dii) is at least one selected from silicone release agents (D1), fluorinated release agents (D2), and aliphatic release agents (D3) each of which has a group including a polymerizable double bond. These agents may be used alone or in combination of two or more.

Examples of the release agent (Dii) include compounds that have at least one structure selected from diaryl silicone structures, dialkyl silicone structures, fluorinated alkyl structures, fluorinated alkenyl structures, and C₈ or higher alkyl structures, and a group including a polymerizable double bond.

In the composition (ii), the content of the release agent (Dii) is preferably from 0.001 to 10% by mass, more preferably from 0.01 to 8% by mass, and still more preferably from 0.03 to 6% by mass based on the total solids content of the composition (ii) taken as 100% by mass. Use of the release agent (Dii) within the range allows for retention of the substrate material on the support via the temporary fixing material during processing of the substrate material and for separation of the substrate material from the support without damaging the substrate material.

<<Silicone Release Agents (D1)>>

The silicone release agents (D1) include a group including a polymerizable double bond. The silicone release agents (D1) have a group including a polymerizable double bond, and thus can be well incorporated into the release layer (II), thereby preventing migration of the (D1) to the other layers such as the layer (I) and preventing contamination of the substrate material by the (D1). The silicone release agents (D1) have excellent heat resistance, and thus can prevent burning of the release layer (II) even after processing at high temperature such as, for example, a temperature of 200° C. or higher.

Preferably, the silicone release agents (D1) have a group including a polymerizable double bond at a side chain or an end of the silicone backbone. The silicone release agents that have a group including a polymerizable double bond at the end are more preferred, because such silicone release agents tend to have both of high initial adhesion and peeling property after processing at high temperature.

The number of groups including a polymerizable double bond in the silicone release agents (B1) is preferably from 1 to 20, more preferably from 2 to 10, and still more preferably from 2 to 8. When the number of the groups including a polymerizable double bond is equal to or larger than the minimum value of the above range, the silicone release agent (D1) can be incorporated into the release layer (II), thereby preventing migration of the agents (D1) to the other layers such as the layer (I) and imparting releasability to the release layer (II). When the number of the groups including a polymerizable double bond is equal to or smaller than the maximum value of the above range, the release layer (II) tends to have sufficient retention of the support.

The weight average molecular weight of the silicone release agents (D1) is, but not limited to, preferably from 300 to 50,000, more preferably from 400 to 10,000, and still more preferably from 500 to 5,000, as measured by GPC relative to polystyrene standards. When the molecular weight is equal to or higher than the minimum value of the above range, the release layer (II) tends to have sufficient heat resistance. When the molecular weight is equal to or lower than the maximum value of the above range, the thermoplastic resin (Aii) and the silicone release agent (D1) can be readily mixed.

A method for synthesizing the silicone release agents (D1) is not particularly limited. Examples of the method include a method of introducing a group including a polymerizable double bond into a silicone resin by hydrosilation reaction of the silicone resin having a SiH group with a vinyl compound having the group including a polymerizable double bond; and a method of condensing a siloxane compound with a siloxane compound having a group including a polymerizable double bond.

Examples of the silicone release agents (D1) include silicone compounds that have at least one structure selected from diaryl silicone structures and dialkyl silicone structures. In particular, silicone compounds that have a group including a polymerizable double bond introduced into a side chain and/or an end of the silicone backbone, as represented by Formula (I), Formula (II), or Formula (III) are suitable. Particularly, silicone compounds that have a group including a polymerizable double bond introduced into the polydimethylsiloxane backbone are preferred.

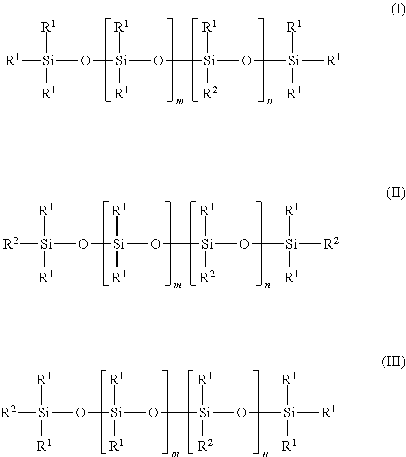

In Formulae (I)-(III), R¹ is each independently a C₆₋₁₅ aryl group or a C₁₋₃₀ alkyl group. The aryl group is preferably a C₆₋₁₀ aryl group, and the alkyl group is preferably a C₁₋₂₀ alkyl group. Particularly preferably, R¹ is each a methyl group.

R² is a group that has a group including a polymerizable double bond, such as, for example, a polyether modified or alkyl modified (meth)acryloyloxy group. m is a natural number that provides a weight average molecular weight of the compound represented by the above Formulae of a value that is within the above-mentioned range.

In Formula (I), n is an integer of 1 or more, preferably from 2 to 10, and more preferably from 2 to 8. In Formula (II), n is an integer of 0 or more, preferably from 0 to 8, and more preferably from 0 to 6. In Formula (III), n is an integer of 0 or more, preferably from 1 to 9, and more preferably from 1 to 7.

In Formula (I)-Formula (III), the —Si(R¹)₂O— units and the —Si(R¹)(R²)O— units may have a random structure or a block structure.

Examples of commercially available silicone release agents (D1) include silicone compounds that have a methacryloyloxy group at the both ends, such as X-22-164, X-22-164AS, X-22-164A, X-22-164B, X-22-164C, and X-22-164E manufactured by Shin-Etsu Chemical Co., Ltd.; silicone compounds that have a methacryloyloxy group at one end, such as X-22-174DX, X-22-2426, and X-22-2475 manufactured by Shin-Etsu Chemical Co., Ltd.; silicone compounds that have an acryloyloxy group, such as EBECRYL 350 and EBECRYL 1360 manufactured by Daicel Cytec Co., Ltd.; silicone compounds that have an acryloyloxy group, such as AC-SQ TA-100 and AC-SQ SI-20 manufactured by Toagosei Co., Ltd.; and silicone compounds that have a methacryloyloxy group, such as MAC-SQ TM-100, MAC-SQ SI-20, and MAC-SQ HDM manufactured by Toagosei Co., Ltd.

Examples of commercially available silicone release agents (D1) also include “Tego Rad 2100” (a penta-functional reactive silicone that has an alkyl modified acryloyloxy group as a functional group), “Tego Rad 2010” (a penta-functional reactive silicone that has an acryloyloxy group as a functional group), “Tego Rad 2250” (a difunctional reactive silicone that has an acryloyloxy group as a functional group), “Tego Rad 2300” (a difunctional reactive silicone that has an alkyl modified acryloyloxy group as a functional group), and “Tego Rad 2600” (an octa-functional reactive silicone that has an alkyl modified acryloyloxy group as a functional group) manufactured by Evonik Degussa Japan Co., Ltd.; “SILAPLANE FM-0711” (a reactive silicone that has an alkyl modified acryloyloxy group as a functional group at one end), and “SILAPLANE FM-7711” (a reactive silicone that has an alkyl modified acryloyloxy group as a functional group at the both ends) manufactured by JNC Corp.; and “BYK-UV 3500” (a polyether modified polydimethylsiloxane that has an acrylic group as a functional group) manufactured by BYK Japan K.K.

<<Fluorinated Release Agents (D2)>>

The fluorinated release agents (D2) have a group including a polymerizable double bond. Examples of the fluorinated release agents (D2) include compounds that have at least one group selected from fluorinated alkyl structures and fluorinated alkenyl structures and a group including a polymerizable double bond.

The fluorinated alkyl structures are, for example, C₁₋₃₀ or preferably C₁₋₂₀ fluorinated alkyl groups (groups in which one or more hydrogens contained in an alkyl group are replaced with a fluorine), and particularly preferably perfluoroalkyl groups.

The fluorinated alkenyl structures are, for example, C₃₋₂₅ or preferably C₅₋₂₀ fluorinated alkenyl groups (groups in which one or more hydrogens contained in an alkenyl group are replaced with a fluorine) and particularly preferably perfluoroalkenyl groups such as groups represented by Formulae (d2-1) or (d2-2). Note that in the present invention, the groups represented by Formulae (d2-1) or (d2-2) have low polymerization reactivity, and thus these groups are not included in a group including a polymerizable double bond.

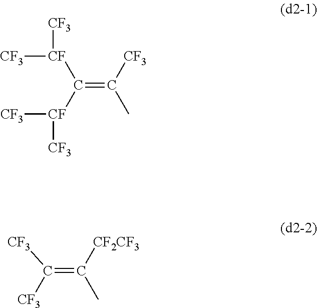

Preferred examples of the fluorinated release agents (D2) include fluorinated release agents that have a fluorinated alkyl structure and a (meth)acryloyl group. The compounds represented by Formula (d2-3) are more preferred.

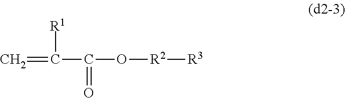

In Formula (d2-3), R¹ is a hydrogen atom or a methyl group, R² is a direct bond or a C₁₋₂₀ alkylene group, and R³ is a C₁₋₃₀ or preferably C₁₋₂₀ fluorinated alkyl group or more preferably a perfluoroalkyl group. Examples of the compounds represented by Formula (d2-3) include 2,2,3,3,3-pentafluoropropyl acrylate and 2-(perfluorobutylethyl)acrylate.

<<Aliphatic Release Agents (D3)>>

The aliphatic release agents (D3) have a group including a polymerizable double bond. Examples of the aliphatic release agents (D3) include compounds that have a C₈ or higher alkyl structure and a group including a polymerizable double bond. The alkyl structure is, for example, a C₈ or higher or preferably C₈₋₄₀ alkyl group. The specific examples include an octyl group, a decanyl group, a dodecyl group, and an octadecyl group.

Preferred examples of the aliphatic release agents (D3) include aliphatic release agents that have a C₈ or higher alkyl structure and a (meth)acryloyl group, and compounds represented by Formula (d3-1) is more preferred.

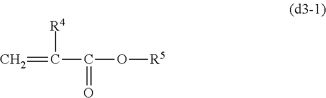

In Formula (d3-1), R⁴ is a hydrogen atom or a methyl group, and R⁵ is a C₈ or higher or preferably C₈₋₄₀ alkyl group. Examples of the compounds represented by Formula (d3-1) include LIGHT ESTER L (n-lauryl methacrylate) and LIGHT ESTER S (n-stearyl methacrylate) manufactured by Kyoeisha Chemical Co., Ltd.

<Radical Polymerization Inhibitor (Eii)>

Preferably, the composition (ii) includes a radical polymerization inhibitor (Eii).

Examples of the radical polymerization inhibitor (Eii) include

phenol compounds such as hydroquinone, pyrogallol, p-methoxyphenol, 4-methoxynaphthol, 4-t-butylcatechol, 2,6-di-t-butyl-4-methylphenol, 2,2′-methylenebis(4-methyl-6-t-butylphenol), 2,2′-methylenebis(4-ethyl-6-t-butylphenol), 2,6-di-t-butyl-N,N-dimethylamino-p-cresol, 2,4-dimethyl-6-t-butylphenol, 4,4′-thio-bis(3-methyl-6-t-butylphenol), 4,4′-butylidene-bis(3-methyl-6-t-butylphenol), 1,3,5-tris(3,5-di-t-butyl-4-hydroxybenzyl)-1,3,5-triazine-2,4,6(1H,3H,5H)-trione, 4,4′,4″-(1-methylpropanil-3-ylidene)tris(6-t-butyl-m-cresol), 6,6′-di-t-butyl-4,4′-butylidenedi-m-cresol, octadecyl-3-(3,5-di-t-butyl-4-hydroxyphenyl)propionate, pentaerythritol tetrakis[3-(3,5-di-t-butyl-4-hydroxyphenyl)propionate], 3,9-bis[2-[3-(3-t-butyl-4-hydroxy-5-methylphenyl)propionyloxy ]⁻1,1-dimethylethyl]-2,4,8,10-tetraoxaspiro[5.5]undecane, and 1,3,5-tris(3,5-di-t-butyl-4-hydroxyphenylmethyl)-2,4,6-trimet hylbenzene;

N-oxy radical compounds such as 4-hydroxy-2,2,6,6-tetramethylpiperidin-N-oxyl, 4-acetamino-2,2,6,6-tetramethylpiperidin-N-oxyl, 4-benzoxy-2,2,6,6-tetramethylpiperidin-N-oxyl, 4-oxo-2,2,6,6-tetramethylpiperidin-N-oxyl, and 2,2,6,6-tetramethylpiperidin-N-oxyl;

amine compounds such as phenothiazine,

N,N′-diphenyl-p-phenylenediamine, phenyl-β-naphthylamine, N,N′-di-β-naphthyl-p-phenylenediamine, and N-phenyl-N′-isopropyl-p-phenylenediamine; hydroxylamine compounds such as 1,4-dihydroxy-2,2,6,6-tetramethylpiperidine and 4-dihydroxy-2,2,6,6-tetramethylpiperidine;

quinone compounds such as benzoquinone and 2,5-di-t-butylhydroquinone; and

copper compounds such as ferrous chloride and copper dimethyldithiocarbamate.

The radical polymerization inhibitor (Eii) may be used alone or in combination of two or more.

Among the radical polymerization inhibitors (Eii), the phenol compounds are preferred, and hindered phenol compounds are more preferred.

In the composition (ii), the content of the radical polymerization inhibitor (Eii) is preferably from 0.1 to 30 parts by mass, more preferably from 1 to 20 parts by mass, and still more preferably from 5 to 15 parts by mass based on 100 parts by mass of the diene polymer (Fii). The content of the (Eii) within the range described above is preferred in that the release layer (II) is not be cured as much as the layer (I), in that the substrate material may be readily separated from the support, and for the thermostability of the composition (ii).

<Diene Polymer (Fii)>

Preferably, the composition (ii) includes a diene polymer (Fii).

Examples of the diene polymer (Fii) can include compounds similar to those listed above for the diene polymer (Fi), and preferred compounds are also similar to those listed above for the diene polymer (Fi). The polymer (Fi) in the composition (i) and the polymer (Fii) in the composition (ii) may be the same or different compound.

In the composition (ii), the content of the diene polymer (Fii) is usually from 1 to 80 parts by mass, preferably from 5 to 50 parts by mass, and more preferably from 10 to 40 parts by mass based on 100 parts by mass of the thermoplastic resin (Aii). The content of the (Fii) within the range described above is preferred for removability with a solvent, adhesion, peeling property, and heat resistance of the temporary fixing material.

2-3. Production of Temporary Fixing Compositions (i) and (ii)

The temporary fixing compositions (i) and (ii) can be produced by mixing the individual ingredients using a known apparatus used to process thermoplastic resins, such as, for example, a twin-screw extruder, a single-screw extruder, a continuous kneader, a roll kneader, a pressure kneader, or a Banbury mixer.

In order to allow the temporary fixing compositions (i) and (ii) to exhibit a viscosity suitable for application, a solvent (G) may be used in the production of the compositions. Examples of the solvent (G) include hydrocarbons such as xylene, limonene, mesitylene, dipentene, pinene, bicyclohexyl, cyclododecene, 1-tert-butyl-3,5-dimethylbenzene, butylcyclohexane, cyclooctane, cycloheptane, cyclohexane, and methylcyclohexane, alcohols/ethers such as anisole, propylene glycol monomethyl ether, dipropylene glycol methyl ether, diethylene glycol monoethyl ether, and diglyme, esters/lactones such as ethylene carbonate, ethyl acetate, n-butyl acetate, ethyl lactate, ethyl 3-ethoxypropionate, propylene glycol monomethyl ether acetate, diethylene glycol monoethyl ether acetate, propylene carbonate, and y-butyrolactone, ketones such as cyclopentanone, cyclohexanone, methyl isobutyl ketone, and 2-heptanone, and amides/lactams such as N-methyl-2-pyrrolidinone.

The inclusion of the solvent (G) in the temporary fixing compositions (i) and (ii) facilitates adjustment of the viscosity of the temporary fixing compositions (i) and (ii), and thus facilitates formation of the temporary fixing material on the substrate material or the support. For example, the solvent (G) can be used so that the total solids content, excluding the solvent (G), of the temporary fixing compositions (i) and (ii) is usually from 5 to 70% by mass and more preferably from 15 to 50% by mass.

The temporary fixing compositions (i) and (ii) may include particles of metal oxides such as aluminum oxide, zirconium oxide, titanium oxide, and silicon oxide, an antioxidant, a polymerization inhibitor, an UV absorber, an adhesion aid, and crosslinked polystyrene particles.

3. Method for treating substrate material

A method for treating the substrate material of the present invention includes <1> a step of forming the stack as described above, <2> a step of processing the substrate material and/or transporting the stack, and <3> a step of separating the substrate material from the support, and optionally, <4> a step of cleaning the substrate material.

The respective steps are hereinafter referred to as steps <1>-<4>.

3-1. Step <1>

In the step <1>, for example, a substrate material can be temporarily fixed on a support by (1-1) forming the temporary fixing material as described above on a surface of the support and/or the substrate material and bonding the substrate material to the support via the temporary fixing material. Alternatively, a substrate material can be temporarily fixed on a support by (1-2) forming the temporary fixing material described above on a surface of the support and forming the substrate material such as a resin coating on the temporary fixing material. The substrate material may be surface-treated, where necessary.

Examples of a method for forming the temporary fixing material include (α) a method of forming the respective layers for the temporary fixing material directly on the support and/or the substrate material and (β) a method of forming a film with a predetermined thickness, by using the temporary fixing composition, on a film such as a release-treated polyethylene terephthalate film and then transferring the respective layers onto the support and/or the substrate material by lamination. The method (a) is preferred for uniformity in film thickness.

Examples of a method for applying the temporary fixing compositions that form the respective layers for the temporary fixing material include spin coating and inkjet printing. Examples of the spin coating, for example, include spin-coating the temporary fixing compositions at a rate of rotation of 300-3,500 rpm and preferably 500-1,500 rpm, an acceleration of 500-15,000 rpm/sec, and a rotation time of 30-300 seconds.

After the temporary fixing compositions are applied to form the coatings, for example, the coatings can be heated by a heater such as a hot plate to evaporate the solvent. For example, the heating conditions are such that the temperature is usually from 150 to 275° C. and preferably from 150 to 260° C., and the period is usually from 2 to 15 minutes and preferably from 3 to 15 minutes.

Especially when the layer (I) is formed, the heating temperature is more preferably from 150 to 250° C. for efficient curing reaction of the polyfunctional (meth)acrylate compound (B) to forma cured layer. When the release agent (Dii) having a group including a polymerizable double bond is used for the release layer (II), the temperature is more preferably from 150 to 250° C. for efficient reaction of the polymerizable double bond.

When the temporary fixing composition (i), which forms the layer (I), includes a photopolymerization initiator, a coating of the composition (i) may be irradiated with light such as ultraviolet light or visible light to drive the curing reaction. When the temporary fixing composition (ii), which forms the layer (II), includes the diene polymer (Fii) and the release agent (Dii) having a functional group that can react with the (Fii) to form a chemical bond, a coating of the composition (ii) may be irradiated with light such as ultraviolet light or visible light to drive the reaction of the (Fii) with the (Dii).

Examples of a method for bonding the substrate material to the support in the method (a) include a method of forming the layer (I) on a circuit surface of the substrate material, forming the release layer (II) on the support, and bonding the layer (I) and the release layer (II) so that the layers become in contact with each other; a method of forming the layer (I) and the release layer (II) on a circuit surface of the substrate material and bonding the support to the release layer (II); and a method of forming the release layer (II) and a precursor layer of the layer (I) on the support, bonding the substrate material to the precursor layer, and curing the precursor layer. The curing temperature is selected as desired depending on factors such as ingredients of the temporary fixing composition and the application method.

Regarding the conditions for pressure-bonding the substrate material and the support, for example, they may be bonded at a temperature of 150-300° C. for a period of 1-5 minutes under a pressure of 0.01-5 MPa. After the pressure-bonding, the substrate material and the support may be heat-treated at a temperature of 150-300° C. for a period of from 10 minutes to 3 hours. In this way, the substrate material is firmly retained onto the support via the temporary fixing material.

Examples of the substrate material to be processed (transported) include semiconductor wafers, glass substrates, resin substrates, metal substrates, metal foils, polishing pads, and resin films. The semiconductor wafers usually include components such as bumps, wires, and insulating films. Examples of the resin films include films including an organic component as a major ingredient. The specific examples include photosensitive resin films formed of a photosensitive material, insulating resin films formed of an insulating material, and photosensitive insulating resin films formed of a photosensitive insulating resin material. Examples of the support include those that are handled easily and have a hard and flat surface, such as glass substrates and silicon wafers.

When the layer (I) is formed on a circuit surface of a substrate material, the circuit surface may be pretreated to allow the temporary fixing material to spread evenly over the surface.

An example of a method for the surface treatment include a method of previously applying a surface treatment agent to the circuit surface. Examples of the surface treatment agent include coupling agents such as silane coupling agents.

3-2. Step <2>

As described above, the step <2> is a step of processing the substrate material temporarily fixed on the support and/or transporting the resultant stack. The transportation step is a step of transporting the substrate material such as a semiconductor wafer from one apparatus to the other apparatus, together with the support. Examples of the processing of the substrate material temporarily fixed on the support include dicing; thinning of substrate materials, such as backgrinding; and photofabrication including one or more treatments selected from etching, sputtered film formation, plating, and reflow plating.

The processing of the substrate may be carried out at any temperature as long as retention of the temporary fixing material is not lost.

3-3. Step <3>

After the processing or transportation of the substrate material, the substrate material is separated from the support by applying a force to the substrate material or the support. Examples of the method include a method of applying a force parallel to a surface of the substrate material to the substrate material or the support to separate the substrate material from the support; and a method of fixing one of the substrate material and the support and lifting the other at a predetermined angle relative to the direction parallel to a surface of the substrate material to separate the substrate material from the support. The latter method is preferred, as the separation successfully occurs in the release layer (II) of the temporary fixing material, and the substrate material can be separated at room temperature.

In particular, a force is preferably applied approximately perpendicularly to a surface of the substrate material to separate the substrate material from the support. The term “a force is applied approximately perpendicularly to a surface of the substrate material” means that a force is usually applied at an angle, relative to a z axis, which is an axis perpendicular to the surface of the substrate material, of from 0° to 60°,preferably from 0° to 45°, more preferably from 0° to 30°, still more preferably from 0° to 5°, and still more preferably 0°, i.e., perpendicularly to the surface of the substrate material.

Examples of a separating method include a method of usually applying a pressure of 0.0001-100 MPa, preferably 0.001-30 MPa, and more preferably 0.005-1 MPa approximately perpendicularly to a surface of the substrate material to separate the substrate material from the support. For example, a periphery of the substrate material or the support can be lifted (part or all of the periphery can be separated from the temporary fixing material), and then the substrate material can be gradually separated from the periphery toward the center of the substrate material or the support while applying a force approximately perpendicularly to a surface of the substrate material (hook pull mode). In the present invention, the substrate material can be separated from the support using such peel force and such separating method.

The substrate material can be separated at usually 5-100° C., preferably 10-45° C., and more preferably15-30° C. The temperature herein refers to the temperature of the support.

To prevent damage to the substrate material during separating the substrate material, a reinforcing tape such as, for example, a commercial dicing tape may be attached to the surface of the substrate material, opposite from the support.

As described above, in the present invention, parts such as bumps are prevented from being damaged during the separating step, as the temporary fixing material includes the layer (I) and the release layer (II), a circuit surface of the substrate material is protected by the layer (I), and the separation occurs mainly in the release layer (II).

3-4. Step <4>

When the temporary fixing material, especially the layer (I), remains on the substrate material after the separating step, such residue can be removed by cleaning the substrate material with a solvent. Examples of the cleaning method include a method of soaking the substrate material in a cleaning liquid, a method of spraying a cleaning liquid to the substrate material, and a method of applying ultrasonic energy to the substrate material soaked in a cleaning liquid. The cleaning liquid may preferably have a temperature of 10-80° C. and more preferably 20-50° C. without limitation.

Examples of the solvent include hydrocarbons such as xylene, limonene, mesitylene, dipentene, pinene, bicyclohexyl, cyclododecene, 1-tert-butyl-3,5-dimethylbenzene, butylcyclohexane, cyclooctane, cycloheptane, cyclohexane, and methylcyclohexane, alcohols/ethers such as anisole, propylene glycol monomethyl ether, dipropylene glycol methyl ether, diethylene glycol monoethyl ether, and diglyme, esters/lactones such as ethylene carbonate, ethyl acetate, n-butyl acetate, ethyl lactate, ethyl 3-ethoxypropionate, propylene glycol monomethyl ether acetate, diethylene glycol monoethyl ether acetate, propylene carbonate, and y-butyrolactone, ketones such as cyclopentanone, cyclohexanone, methyl isobutyl ketone, and 2-heptanone, and amides/lactams such as N-methyl-2-pyrrolidinone.

When a cycloolefin polymer is used as the thermoplastic resin (Ai), which is one of ingredients forming the layer (I), it is preferred to use a less polar organic solvent. For example, the hydrocarbons as listed above are preferred.

In this way, the substrate material can be separated from the support.

4. Semiconductor Device

A semiconductor device of the present invention is obtained by the treatment method of the present invention. Because the temporary fixing materials as described above can be easily removed when a semiconductor device (for example, a semiconductor element) is separated, the semiconductor device exhibits significantly reduced damage to parts such as bumps formed on a circuit surface and significantly reduced contamination (for example, staining and burning) due to the temporary fixing material.

### Examples

Now, the present invention will be more specifically described with reference to examples, although the present invention is not limited to the examples. As used hereinafter, “parts” refers to “parts by mass” unless otherwise mentioned.

The weight average molecular weight (Mw) and the number average molecular weight (Mn) of polymers and resins were measured on “HLC-8220-GPC” instrument (manufactured by Tosoh Corp.) with GPC columns (two G2000 HXL columns, one G3000 HXL column, and one G4000 HXL column) manufactured by Tosoh Corp. using a polystyrene standard.

### Example 1A

100 parts of a cycloolefin polymer (under the trade name of “ARTON R5300” from JSR Corp.), 5 parts of a difunctional acrylate (under the trade name of “NK ESTER A-400” from Shin-Nakamura Chemical Co., Ltd.), 1 part of a radical polymerization initiator (under the trade name of “PERCUMYL P” from NOF Corp.), 30 parts of a liquid styrene-butadiene rubber (under the trade name of “L-SBR-820” from Kuraray Co., Ltd.), and 300 parts of mesitylene were mixed at 25° C. to prepare a temporary fixing composition 1 of Example 1A.

### Examples 2A-5A and Preparation Example 1A

Temporary fixing compositions 2-6 of Examples 2A-5A and Preparation Example 1A were prepared in the same manner as in Example 1A except that the composition was changed as indicated in Tables 1.

TABLE 1

| | | Example | Example | Example | Example | Example | Preparation |
|---|---|---|---|---|---|---|---|
| | | 1A | 2A | 3A | 4A | 5A | Example 1A |
| Temporary fixing composition | | 1 | 2 | 3 | 4 | 5 | 6 |
| (A) Thermoplastic resin | A1 | 100 | 100 | 100 | | 100 | 100 |
| | A2 | | | | 100 | | |
| (B) Polyfunctional (meth)acrylate compound | B1 | 5 | | | 5 | | |
| | B2 | | 5 | | | | |
| | B3 | | | 5 | | 5 | |
| (C) Radical polymerization initiator | C1 | 1 | 1 | 1 | 1 | 1 | |
| (D) Release Agent | D1 | | | | | | 1 |
| (E) Radical polymerization inhibitor | E1 | | | | | | 3 |
| (F) Diene polymer | F1 | 30 | 30 | 30 | 30 | | 30 |
| (G) Solvent | G1 | 300 | 300 | 300 | 300 | 240 | 300 |

The values for the individual ingredients indicate parts by mass.

Now, the individual ingredients used in Examples will be described in detail.

A1: “ARTON R5300” from JSR Corp.

A2: “ZEONEX 480R” from Zeon Corp.

B1: Difunctional acrylate under the trade name of “NK ESTER A-400” from Shin-Nakamura Chemical Co., Ltd.

B2: Difunctional acrylate under the trade name of “NK ESTER A-BPE-10” from Shin-Nakamura Chemical Co., Ltd.

B3: Trifunctional acrylate under the trade name of “NK ESTER A-GLY-9E” from Shin-Nakamura Chemical Co., Ltd.

C1: Product containing diisopropylbenzene hydroperoxide under the trade name of “PERCUMYL P” from NOF Corp.

D1: Polyethermodified polydimethylsiloxane having an acryl group under the trade name of “BYK-UV3500” from BYK Japan K.K.

E1: Hindered phenol polymerization inhibitor under the trade name of “ADK STAB A0-60” from ADEKA Corp.

F1: Liquid styrene-butadiene rubber under the trade name of “L-SBR-820” from Kuraray Co., Ltd.

G1: Mesitylene

### Example 1B

The temporary fixing composition 1 was spin-coated onto a 4-inch silicon wafer (substrate material) having a plurality of bumps thereon. The coated wafer was heated on a hot plate in the atmosphere at 160° C. for 5 minutes to obtain a substrate having a film (the temporary fixing material layer (I)) with a thickness of 40 μm. The resultant substrate was cut into 1 cm by 1 cm pieces to obtain a substrate 1A that has the temporary fixing material layer (I).

The bumps had a length of 20 μm, a width of 20 μm, and a height of 20 μm. The lower half of the bumps on the silicon wafer side was a copper pillar portion and the upper half was a Sn—Ag alloy solder portion.

Next, the temporary fixing composition 6 was spin-coated onto a 4-inch silicon wafer (support). The coated wafer was heated on a hot plate in the atmosphere at 160° C. for 5 minutes to obtain a substrate having a film (the temporary fixing material layer (II)) with a thickness of 40 μm. The resultant substrate was cut into 2 cm by 2 cm pieces to obtain a substrate 1B that has the temporary fixing material layer (II).

The substrate 1A and the substrate 1B were bonded together so that the temporary fixing material layer (I) became contact with the temporary fixing material layer (II). A pressure of 0.05 MPa was applied at 160° C. for 60 seconds using a die bonder. Then, the bonded substrates were heated at 200° C. for an hour to form a stack of the silicon wafer (substrate material), the temporary fixing material layer (I), the temporary fixing material layer (II), and the silicon wafer (support), which were arranged in this order.

A shear force was applied (at a rate of 500 μm/sec and at 23° C.) in the direction parallel to a surface of the substrate material using a universal bond tester (under the trade name of “DAGE 4000” from Dage Japan Co. , Ltd.). It was able to be confirmed that even when a pressure of 2 MPa is applied, the silicon wafer (substrate material) and the silicon wafer (support) remained bonded together (temporarily fixed) without any displacement.

[Peeling Property Test]

Next, peeling property test was performed. A force was applied (at a rate of 500 μm/sec and at 23° C.) to the stack along an axis (Z axis) perpendicular to a surface of substrate material using a universal bond tester (under the trade name of “DAGE 4000” from Dage Japan Co., Ltd.) in a hook pull mode (at 0° relative to the Z axis). As a result, the silicon wafer (substrate material) was able to be separated from the silicon wafer (support) at a pressure of less than 0.3 MPa without separation of the bumps on the silicon wafer (substrate material).

[Cleanability Test]

The silicon wafer (substrate material) after the peeling property test having a residue of the temporary fixing material was soaked in mesitylene at 23° C. for 5 or 10 minutes. After soaking for 5 minutes, the residue of the temporary fixing material was removed from the silicon wafer (substrate material), which confirmed that the temporary fixing material had good cleanability.

### Examples 2B-5B and Comparative Examples 1B-2B

Examples and comparative examples were carried out in the same manner as in Example 1B except that the combination of the temporary fixing compositions was changed as indicated in Table 2. The results are shown in Table 2.

TABLE 2

| | | | | | | Comparative | Comparative |
|---|---|---|---|---|---|---|---|
| | Example 1B | Example 2B | Example 3B | Example 4B | Example 5B | Example 1B | Example 2B |
| Temporary fixing | Temporary | Temporary | Temporary | Temporary | Temporary | Temporary | Temporary |
| material layer in | fixing | fixing | fixing | fixing | fixing | fixing | fixing |
| contact with | composition | composition | composition | composition | composition | composition | composition |
| substrate material | 1 | 2 | 3 | 4 | 5 | 6 | 6 |
| Temporary fixing | Temporary | Temporary | Temporary | Temporary | Temporary | Temporary | Temporary |
| material layer in | fixing | fixing | fixing | fixing | fixing | fixing | fixing |
| contact with support | composition | composition | composition | composition | composition | composition | composition |
| | 6 | 6 | 6 | 6 | 6 | 1 | 2 |
| Peeling property Test | A | A | A | A | A | B | B |
| A: No bumps were | | | | | | | |
| separated. | | | | | | | |
| B: Some bumps were | | | | | | | |
| separated. | | | | | | | |
| Cleanability Test | A | A | B | A | C | — | — |
| A: No residue remained | | | | | | | |
| after soaking for 5 | | | | | | | |
| minutes. | | | | | | | |
| B: No residue remained | | | | | | | |
| after soaking for 10 | | | | | | | |
| minutes. | | | | | | | |
| C: A residue remained | | | | | | | |
| even after soaking for | | | | | | | |
| 10 minutes. | | | | | | | |

—: Some bumps were separated, and thus the evaluation was not made.

REFERENCE SIGNS LIST

| | |
|---|---|
| 1 | stack |
| 10 | support |
| 20 | temporary fixing material |
| 21 | layer (I) |
| 22 | release layer (II) |
| 30 | substrate material |
| 31 | bump |
| 101, 102 | residue of temporary fixing material |

What is claimed is:

1. A stack comprising a substrate material that has a circuit surface and that is temporarily fixed on a support via a temporary fixing material,
wherein the temporary fixing material comprises
a temporary fixing material layer (I) that is in contact with the circuit surface of the substrate material, and
a temporary fixing material layer (II) that is formed on the support-facing surface of the layer (I),
wherein the temporary fixing material layer (I) is formed of a temporary fixing composition (i) that comprises a thermoplastic resin (Ai), a polyfunctional (meth)acrylate compound (Bi), and a radical polymerization initiator (Ci), and
wherein the temporary fixing material layer (II) is formed of a temporary fixing composition (ii) that comprises a thermoplastic resin (Aii) and a release agent (Dii).

2. The stack according to claim 1, wherein the temporary fixing composition (ii) does not substantially comprise a radical polymerization initiator (Cii).

3. The stack according to claim 1, wherein the temporary fixing composition (ii) further comprises a radical polymerization inhibitor (Eii).

4. The stack according to claim 1, wherein the temporary fixing composition (i) comprises a difunctional (meth)acrylate as the polyfunctional (meth)acrylate compound (Bi).

5. The stack according to claim 1, wherein the temporary fixing composition (i) has a content of the polyfunctional (meth)acrylate compound (Bi) of 0.5-50 parts by mass based on 100 parts by mass of the thermoplastic resin (Ai).

6. The stack according to claim 1, wherein the temporary fixing composition (i) further comprises a diene polymer (Fi).

7. A method for treating a substrate material, the method comprising <1> a step of forming the stack according to claim 1, <2> a step of processing the substrate material and/or transporting the stack, and <3> a step of separating the substrate material from the support.

8. The treatment method according to claim 7, the method further comprising <4> a step of cleaning the substrate material.

9. A temporary fixing composition comprising a thermoplastic resin (Ai), a polyfunctional (meth)acrylate compound (Bi), and a radical polymerization initiator (Ci).

10. A semiconductor device obtained by the treatment method according to claim 7.
